(19) United States
(12) Patent Application Publication
(10) Pub. No.: US 2011/0156568 A1
(43) Pub. Date: Jun. 30, 2011

(54) ASSEMBLY OF HEAT DISSIPATING MODULE

(76) Inventors: SHYH-MING CHEN, Taipei (TW); Xiang Lin You, Taipei (TW)

(21) Appl. No.: 12/975,360

(22) Filed: Dec. 22, 2010

(30) Foreign Application Priority Data
Dec. 31, 2009 (TW) 098224838

(51) Int. Cl. H01J 61/52; H05K 7/20; F28F 7/00; B21J 15/02

(52) U.S. Cl. 313/46; 361/718; 165/185; 29/525.06

(57) ABSTRACT

An assembly of heat dissipating module includes an aluminum substrate having a first surface and an opposite second surface with at least one connection portion, a heat sink having a plurality of heat dissipating fin and a contact surface, at least one press mold arranged to the heat sink, and a connection component connecting the press mold to the aluminum substrate.

### FIELD OF THE INVENTION

The present invention relates to heat dissipating device, and particular to an assembly of heat dissipating device for lamp or electronic device with a high thermal conductivity and simplified assembly and manufacture.

### DESCRIPTION OF THE PRIOR ART

Dissipation of heat generated by an operating computer or electronic device is very important for stable performance and lifetime of the device.

In the field of illumination, LED lamp is taking the place of conventional bulb or mercury lamp by advantages of its size, power consumption, performance, and lifetime. However, LED also has a heat problem which will damage the lifetime seriously.

Prior heat dissipating device includes a base having a plurality of fin which is attached to a LED aluminum substrate. The base and the aluminum substrate are assembled by welding so that heat can be conducted to the fins for dissipation.

However, welding process takes long time and gaps will be easily formed by the point contact or large interval between welding points. Thermal conductivity will be damaged by such process.

### SUMMARY OF THE PRESENT INVENTION

Accordingly, the primary object of the present invention is to provide an assembly of heat dissipating module by directly attaching a heat sink with fins to an aluminum substrate attached by a heat source so as to improve the attachment and performance.

The secondary object of the present invention is to simplify process of assembling the heat sink and the aluminum substrate so as to avoid defects of the welding process. Flexibility of assembling and convenience can be achieved by availability of applying different shape of the heat sink and aluminum substrate with an optional heat pipe.

### BRIEF DESCRIPTION OF THE DRAWINGS

FIG. 1 is an exploded view of the present invention.

FIG. 2 is a schematic view showing the assembling of the present invention.

FIG. 3 is a schematic view of the present invention.

FIG. 4 is a side view of the present invention.

FIG. 5 is a schematic view of another embodiment of the present invention.

FIG. 6 is a schematic view of yet another embodiment of the present invention.

FIG. 7 is a schematic view of yet another embodiment of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

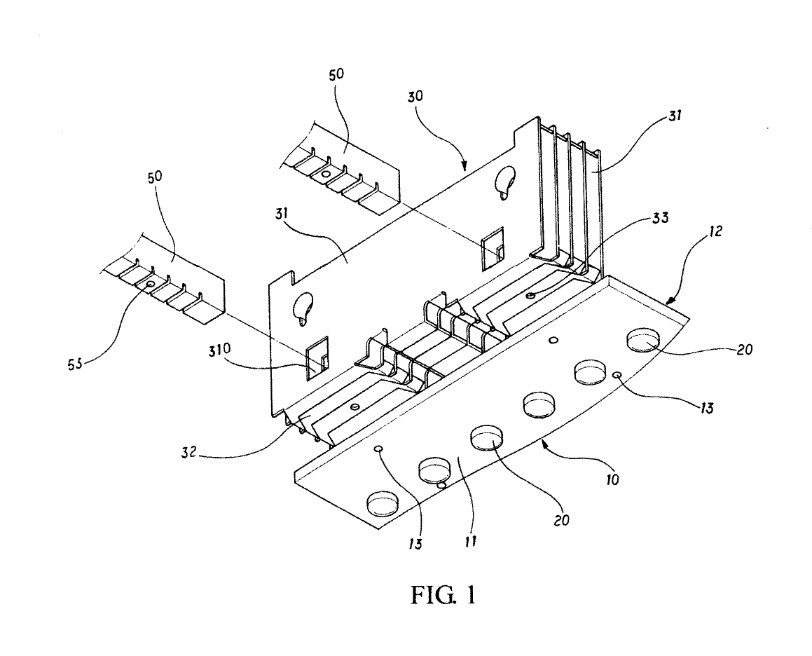

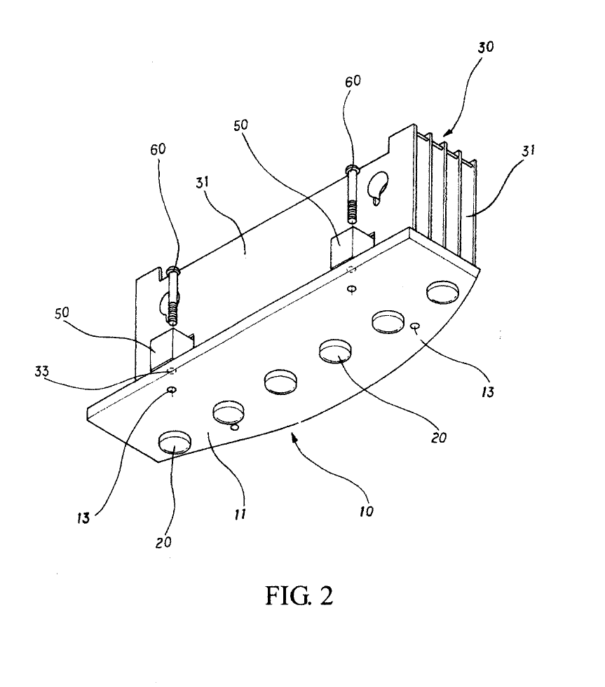

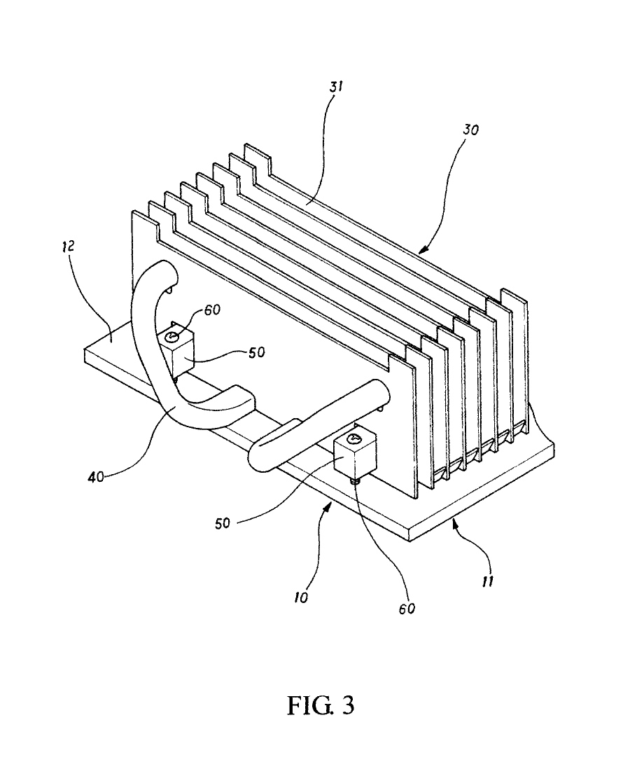

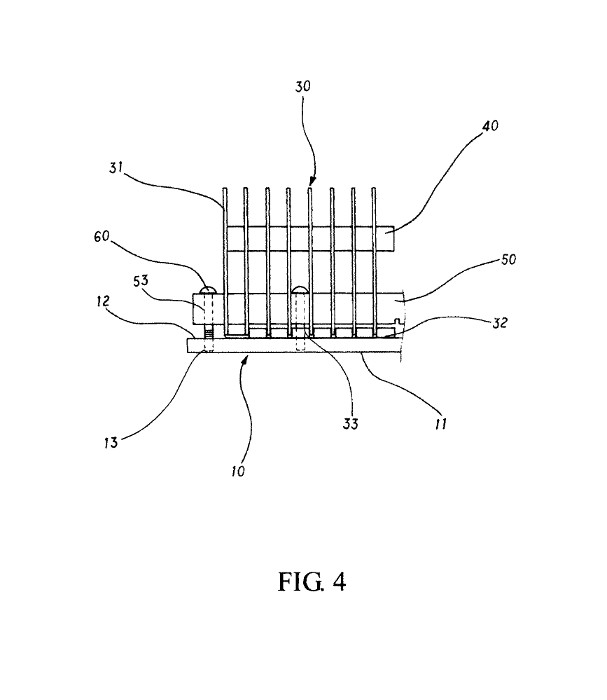

Referring to FIGS. 1 to 4, an assembly of heat dissipating module according to the present invention includes an aluminum substrate 10, heat sink 30, at least one press mold 50, and at least on connection component 60. The aluminum substrate 10 has a first surface 11 and a second surface 12 on the opposite side of the first surface 11. A heat source 20 of a LED lamp is arranged to the first surface 11. The heat source applied to the present invention can also be an integrated circuit such as a CPU arranged to the second surface 12. At least one connection portion 13 is formed to the second surface 12. The connection portion 13 is one of a through hole, blind hole, or post hole with optional inner thread.

The heat sink 30 has a plurality of heat dissipating fin 31 and a contact surface 32 attaching to the second surface 12 of the aluminum substrate 10. A heat conducting medium (not shown) is smeared between the contact surface 32 and the aluminum substrate 10. At least one heat pipe 40 is arranged between the aluminum substrate 10 and the plurality of heat dissipating fin 31. The heat sink 30 has through holes 33 for the connection portion 13. Each heat dissipating fin 31 has a open hole 33 for being penetrated by the press mold 50.

The embodiment shown in the Fig. has two press molds 50 arranged to the open holes 310 of the heat sink 30, and the heat dissipating fins 31 and the second surface 12 of the aluminum substrate 10 are engaged by the press molds 50. Axial holes 53 corresponding to the through holes 33 of the heat sink 30 are formed to the press mold 50. The open holes 310 are formed near to the contact surface 32 so that the press molds 50 penetrating the through holes 310 can be tightly attached to a rear side of the contact surface 32.

The connection component 60 links the axial hole 53 of the press mold 50 and the through hole 33 of the heat sink 30 so that the press mold 50 can engage the heat sink 30 to the second surface 12 of the aluminum substrate 10 by being fixed to the connection portion 13. The fixing can be done by screwing, buckling, riveting, or press fitting.

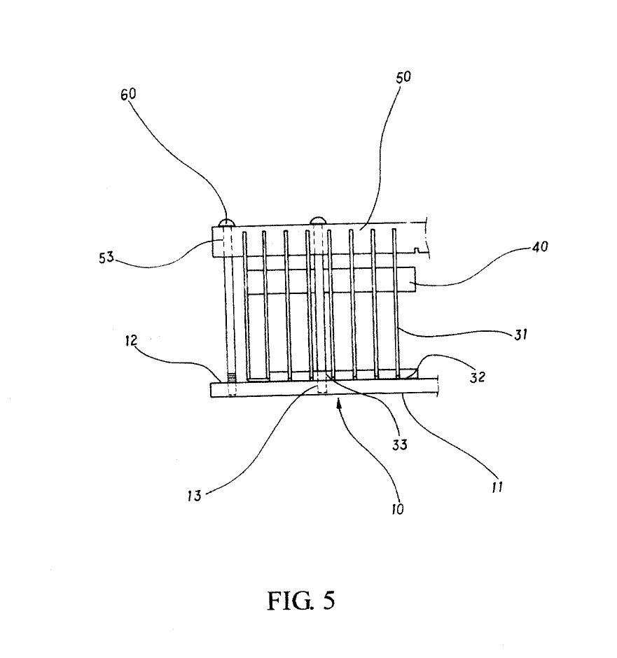

Referring to FIG. 5, another embodiment of the present invention includes an aluminum substrate 10, heat sink 30, press mold 50 and a connection component 60. The heat sink 30 has a plurality of heat dissipating fin 31 and a contact surface 32 attaching to the second surface 12 of the aluminum substrate 10. The heat sink 30 has through holes 33 corresponding to the connection portion 13 (refer to FIG. 1). The press mold 50 is arranged to a side of the heat sink 30 opposite to one of the contact surface 32 so as to engage the contact surface 32 of the heat dissipating fins 31 to the second surface 12 of the aluminum substrate 10. The press mold 50 has axial holes 53 corresponding to the through holes 33 of the heat sink 30.

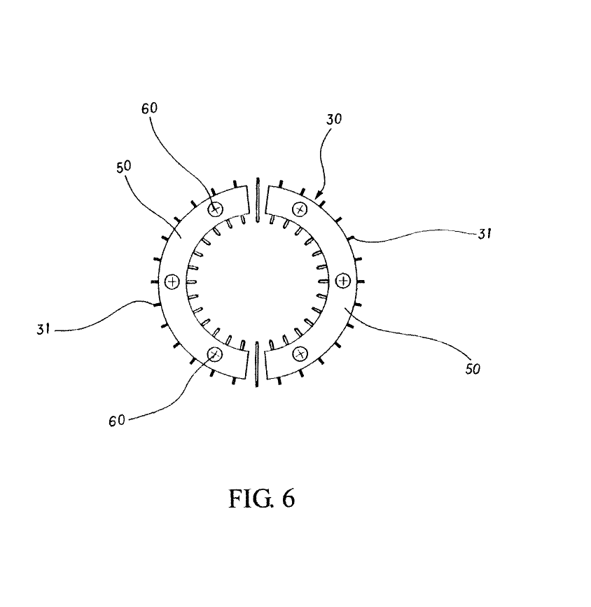

Referring to FIG. 6, a yet embodiment of the present invention is illustrated. A press mold 50 of the embodiment is also arranged to a side of the heat sink 30 opposite to one of a contact surface 32 so as to engage the contact surface 32 to a second surface 12 of an aluminum substrate 10.

The heat sink 30 is a cylinder of roundly assembled heat dissipating fins 31. The press mold 50 is a hollow ring or a ring plate in one or two pieces. The press mold 50 has axial holes 53 corresponding to through holes 33 of the heat sink 30 (refer to FIG. 1). Through connection components 60 connecting the axial holes 53 of the press mold 50 and the through holes 33 of the heat sink 30, the contact surface 32 can be tightly fixed to a connection portion 13 of the second surface 12 of the aluminum substrate 10.

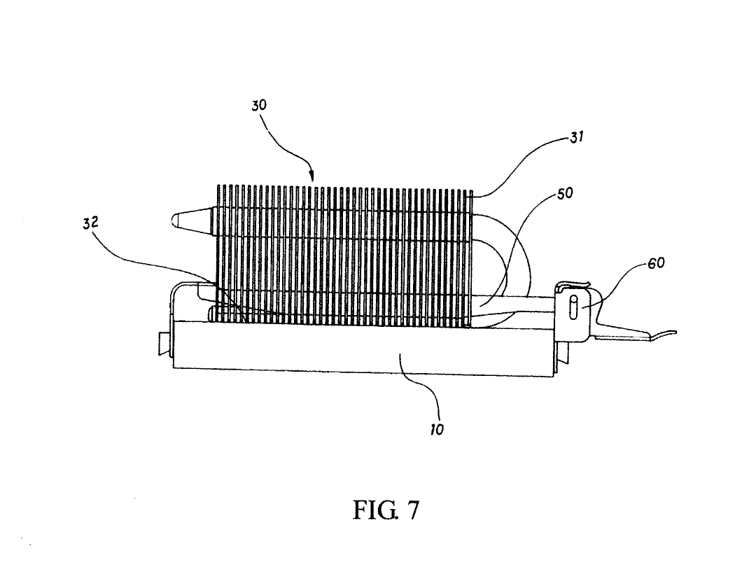

Moreover, a yet embodiment of the present invention is illustrated in FIG. 7. The heat sink 30 of the embodiment includes a plurality of heat dissipating fin 31. The press mold 50 is a press arm and a connection component 60 is a buckle unit. The press mold 50 penetrates open holes 310 of the heat dissipating fins 31 (refer to FIG. 1). One end of the press mold 50 is arranged to an aluminum substrate 10 and the connection component 60 is formed to the other end thereof. A contact surface 32 of the heat sink 30 is attached to the aluminum substrate 10 through the buckling.

Through above features, the heat sink 30 can be tightly attached to the aluminum substrate 10 by the connection component 60 and the press mold 50 so that heat dissipation from a heat source 20 can be improved.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An assembly of heat dissipating module comprising:
an aluminum substrate having a first surface and an opposite second surface; the second surface having at least one connection portion;
a heat sink having a plurality of heat dissipating fin; the heat sink further having a contact surface and through holes;
at least one press mold arranged to the heat sink for engaging the heat sink to the second surface of the aluminum substrate; the press mold having axial holes corresponding to the through holes of the heat sink;
at least one connection component linking the axial hole and of the press mold and the through hole of the heat sink so as to tightly engage the contact surface of the heat sink with the second surface of the aluminum substrate.

2. The assembly of heat dissipating module as claimed in claim 1, wherein a heat source is arranged to one of the first or second surface of the aluminum substrate.

3. The assembly of heat dissipating module as claimed in claim 1, wherein the at least one connection component of the aluminum substrate is a hole.

4. The assembly of heat dissipating module as claimed in claim 3, wherein the connection component of the aluminum substrate is one of a through hole, blind hole, or post hole.

5. The assembly of heat dissipating module as claimed in claim 3, wherein the connection component is one of a threaded through hole, blind hole, or post hole.

6. The assembly of heat dissipating module as claimed in claim 1, wherein each heat dissipating fin has at least one open hole for being penetrated by the press mold; the connection component links the axial hole of the press mold and the through hole of the heat sink so as to tightly connect the contact surface and the second surface.

7. The assembly of heat dissipating module as claimed in claim 1-6, wherein the heat sink further includes a heat pipe fixed to the aluminum substrate and the plurality of heat dissipating fin.

8. The assembly of heat dissipating module as claimed in claim 1-6, wherein a heat conducting medium is smeared between the contact surface of the heat sink and the second surface of the aluminum substrate.

9. The assembly of heat dissipating module as claimed in claim 1-6, wherein the connection component passing through the axial hole is fixed to the connection portion of the second surface by one method of screwing, riveting, buckling, or press fitting.

10. The assembly of heat dissipating module as claimed in claim 1, wherein each heat dissipating fin has at least one open hole communicates to one of the adjacent heat dissipating fin; the open holes are formed near to the contact surface of the heat sink; the press mold passing through the open holes and pressing the contact surface is fixed to the heat dissipating module; the connection component links the axial hole of the press mold and the through hole of the heat sink so as to tightly connect the contact surface and the second surface of the aluminum substrate.

11. The assembly of heat dissipating module as claimed in claim 1, wherein the heat source is one of a LED lamp or an integrated circuit such as a CPU.

12. The assembly of heat dissipating module comprising:
an aluminum substrate having a first surface and an opposite second surface; the second surface having at least one connection portion;
a heat sink having a plurality of heat dissipating fin; the heat sink further having a contact surface corresponding to the second surface;
at least one press mold arranged to the heat sink for engaging the heat dissipating fin;
at least one connection component connecting the press mold engaging the heat dissipating fin to the second surface of the aluminum substrate.

13. The assembly of heat dissipating module as claimed in claim 12, wherein the connection component links the press mold and the connection portion by a method of screwing, riveting, buckling, or press fitting.

14. The assembly of heat dissipating module as claimed in claim 12, wherein a heat source is arranged to one of the first or second surface of the aluminum substrate.

15. The assembly of heat dissipating module as claimed in claim 12, wherein a heat source is one of a LED lamp or an integrated circuit such as a CPU.

16. The assembly of heat dissipating module as claimed in claim 12, wherein the press mold is a press arm and the connection component is a buckle unit.
